(19) United States
(12) Patent Application Publication
(10) Pub. No.: US 2025/0056728 A1
(43) Pub. Date: Feb. 13, 2025

(54) FLEXIBLE TRANSPARENT WIRING BOARD AND METHOD FOR MANUFACTURING FLEXIBLE TRANSPARENT WIRING BOARD

(71) Applicant: NIPPON MEKTRON, LTD., Tokyo (JP)

(72) Inventors: Akihiro NAKAMURA, Tokyo (JP); Masahiro BUSHIMATA, Tokyo (JP)

(73) Assignee: NIPPON MEKTRON, LTD., Tokyo (JP)

(21) Appl. No.: 18/738,547

(22) Filed: Jun. 10, 2024

(30) Foreign Application Priority Data
Aug. 7, 2023 (JP) 2023-128329

(51) Int. Cl. H05K 1/18; H05K 1/03; H05K 3/00; H05K 3/10; H05K 3/40

(52) U.S. Cl. CPC H05K 1/183; H05K 1/0393; H05K 3/0026; H05K 3/107; H05K 3/4038; H05K 2201/09036; H05K 2201/09827; H05K 2203/0264

(57) ABSTRACT

Provided is a flexible transparent wiring board which includes a base substrate, and wiring, in which the base substrate is transparent and has flexibility and insulating properties, a groove is formed on an upper surface of the base substrate, the wiring is formed of a wiring constituent material filled in the groove, and the groove is formed in a narrow V-shape in a depth direction.

### CROSS-REFERENCE TO RELATED APPLICATION

This application claims priority from Japanese Patent Application No. 2023-128329 filed with the Japan Patent Office on Aug. 7, 2023, the entire content of which is hereby incorporated by reference.

### BACKGROUND

### 1. Technical Field

The present invention relates to a flexible transparent wiring board and a method for manufacturing the flexible transparent wiring board.

### 2. Related Art

Flexible transparent wiring boards described in JP-T-2011-528502 and JP-A-2006-120888 include a base substrate having a pattern of grooves formed on an upper surface, and a wiring pattern formed by a wiring constituent material filled in the grooves. A width of the groove is substantially constant regardless of a position in a depth direction.

### SUMMARY

A flexible transparent wiring board according to an embodiment of the present disclosure is configured to include a base substrate, and wiring, in which the base substrate is transparent and has flexibility and insulating properties, a groove is formed on an upper surface of the base substrate, the wiring is formed of a wiring constituent material filled in the groove, and the groove is formed in a narrow V-shape in a depth direction.

### BRIEF DESCRIPTION OF THE DRAWINGS

FIG. 1 is a cut end view of a flexible transparent wiring board, and illustrates a cross-section perpendicular to an extending direction of a wiring pattern;

FIG. 2 is a schematic plan view of the flexible transparent wiring board;

FIGS. 3A and 3B are partially enlarged views of portion A illustrated in FIG. 1. FIG. 3A illustrates a state in which an upper surface of a wiring constituent material is a recessed surface recessed toward a widthwise central portion, and FIG. 3B illustrates a state in which a height position of the upper surface of the wiring constituent material is lower than that of an opening of a groove;

FIGS. 4A and 4B are partially enlarged views of the wiring pattern, FIG. 4A is a cross-sectional view perpendicular to the extending direction of the wiring pattern, and FIG. 4B is a side view of the wiring pattern viewed in a direction of an arrow A illustrated in FIG. 4A;

FIGS. 5A, 5B, and 5C are cut end views for explaining a method for manufacturing the flexible transparent wiring board, FIG. 5A illustrates a step of preparing a laminate, FIG. 5B illustrates a step of patterning the groove, and FIG. 5C illustrates a step of forming the wiring pattern;

FIGS. 6A and 6B are cut end views for explaining the method for manufacturing the flexible transparent wiring board, FIG. 6A illustrates a step of peeling off a protective layer, and FIG. 6B illustrates a step of attaching an insulating cover to a base substrate;

FIG. 7 is a partially enlarged view of a cut end surface of the flexible transparent wiring board, and illustrates an example in which the groove is formed in a narrow U-shape in a depth direction;

FIGS. 8A, 8B, and 8C are cut end views for explaining the method for manufacturing the flexible transparent wiring board, and illustrate a step of forming a groove narrower than a diameter of a laser beam;

FIGS. 9A, 9B, and 9C are cut end views for explaining the method for manufacturing the flexible transparent wiring board, and illustrate a step of forming a groove wider than the diameter of the laser beam;

FIGS. 10A, 10B, 10C, and 10D are views illustrating images taken of the cross-section of the flexible transparent wiring board in the step of patterning the groove, and illustrate a step of forming a laser processed groove in the laminate by irradiating the laser beam;

FIG. 11 is a view illustrating an image taken of the cross-section of the flexible transparent wiring board, and illustrates the state in which the upper surface of the wiring constituent material is the recessed surface recessed toward the widthwise central portion; and

FIG. 12 is a view illustrating an image taken of the cross-section of the flexible transparent wiring board, and illustrates a state in which a carbon layer is formed on the wiring constituent material.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to the study of the present inventors, there is a room for improvement in flexible transparent wiring boards described in JP-T-2011-528502 and JP-A-2006-120888 from the viewpoint of achieving good transparency, stretchability, and bending resistance of the flexible transparent wiring board.

The present disclosure relates to a flexible transparent wiring board having a structure capable of achieving good transparency, stretchability, and bending resistance, and a method for manufacturing the flexible transparent wiring board.

A flexible transparent wiring board according to an embodiment of the present disclosure includes a base substrate, and wiring, in which the base substrate is transparent and has flexibility and insulating properties, a groove is formed on an upper surface of the base substrate, the wiring is formed of a wiring constituent material filled in the groove, and the groove is formed in a narrow V-shape in a depth direction.

A method for manufacturing a flexible transparent wiring board according to the present disclosure includes: preparing a laminate including a base substrate that is transparent and has flexibility and insulating properties, and a protective layer that is releasably attached to an upper surface of the base substrate; forming a groove in the base substrate by irradiating the base substrate with a laser beam through the protective layer of the laminate; forming wiring by filling the groove with a wiring constituent material and drying; and peeling the protective layer from the base substrate, in which the groove is formed in a narrow V-shape in a depth direction.

According to the present disclosure, it is possible to achieve good transparency, stretchability, and bending resistance of the flexible transparent wiring board.

Embodiments of the present disclosure will be described below with reference to the drawings. Note that in all the drawings, the same components are denoted by the same reference numerals, and descriptions thereof will be omitted as appropriate.

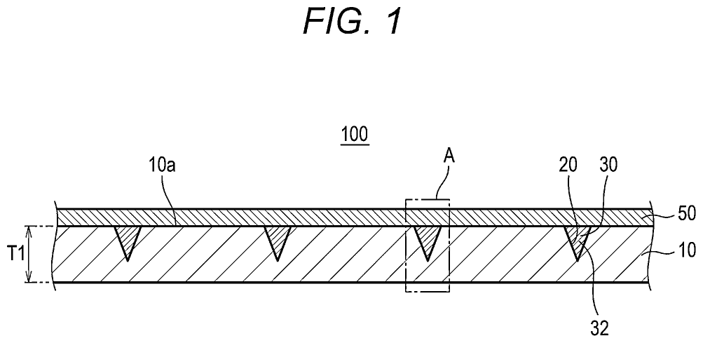

Note that when describing a positional relationship and the like of components of a flexible transparent wiring board 100 below, an upper side in FIG. 1 is referred to as upper side or above, and the opposite side is referred to as lower side or below. However, definitions of these directions are for convenience, and do not limit directions when manufacturing and using the flexible transparent wiring board 100.

As illustrated in FIGS. 1 to 3B, the flexible transparent wiring board 100 according to the present embodiment is transparent, has flexibility and insulating properties, and includes a base substrate 10 having a groove 20 formed in an upper surface 10a, and a wiring (wiring pattern 30) formed of a wiring constituent material 32 filled in the groove 20.

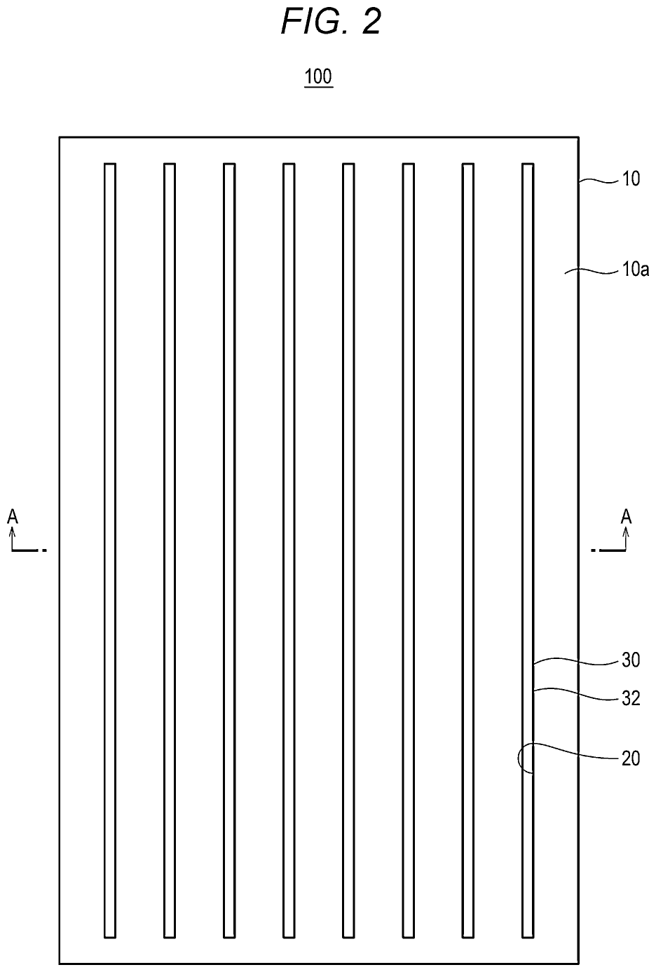

Note that in the present embodiment, the groove 20 is patterned as illustrated in FIG. 2. In the present embodiment, the wiring filled in the pattern of the groove 20 may be referred to as the wiring pattern 30.

The pattern of the groove 20 and the wiring pattern 30 are not limited to a pattern illustrated in FIG. 2, and can be any desired pattern. For example, a plurality of the wiring patterns 30 is not limited to a linear pattern as illustrated in FIG. 2, but may be bent. Further, intervals between the wiring patterns 30 are not limited to equal intervals as illustrated in FIG. 2.

The groove 20 is formed in a narrow V-shape in a depth direction.

Note that “transparent” here means transparent to visible light.

Further, the term “an upper surface of the base substrate 10” here means a surface on a side where a part of the wiring pattern 30 is exposed from the base substrate 10, among front and back main surfaces of the base substrate 10. However, definition of the upper surface here is for convenience, and does not limit a direction when manufacturing and using the flexible transparent wiring board 100.

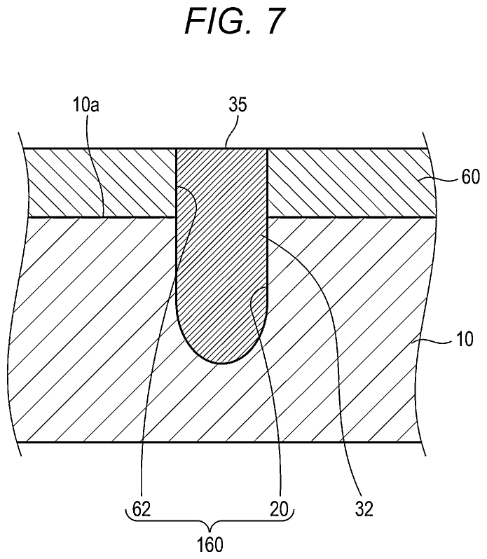

Further, the “V-shape” here includes, for example, a U-shape as illustrated in FIG. 7.

According to the present embodiment, the groove 20 is formed in a narrow V-shape in the depth direction. Therefore, even when the groove 20 is set to have a narrow width, when the groove 20 is filled with the wiring constituent material 32, the wiring constituent material 32 can smoothly flow into the entire inside of the groove 20 due to capillary action. Therefore, the narrow wiring pattern 30 can be easily formed. Thus, a formation region of the wiring pattern 30 on the base substrate 10 can be kept to a minimum, so that it is possible to suppress the transparency, stretchability, and bending resistance of the base substrate 10 from being impaired. That is, according to the present embodiment, it is possible to achieve good transparency, stretchability, and bending resistance of the flexible transparent wiring board 100.

The flexible transparent wiring board 100 according to the present embodiment is used, for example, as a wiring board for a vehicle-mounted antenna attached to glass, a sensor attached to glass, a switch, a wearable device, a touch panel, and the like.

Further, the flexible transparent wiring board 100 is used, as an example, by being attached to an object to be attached. In this case, the flexible transparent wiring board 100 expands, contracts, and curves following irregularities and deformation of the object to be attached.

The base substrate 10 is, for example, a relatively thin film-like substrate having front and back sides of main surfaces.

The base substrate 10 is made of a transparent resin material having insulating properties and flexibility, and is made of polyethylene terephthalate (PET) in the present embodiment. However, material of the base substrate 10 is not limited to this example, and may be, for example, polyimide (PI), polyethylene naphthalate (PEN), liquid crystal polymer (LCP), fluorine-based resin (polytetra-fluoroethylene: PTFE), or a resin material containing them.

As illustrated in FIG. 1, the wiring pattern 30 is formed on the upper surface 10a of the base substrate 10. The wiring pattern 30 is electrically connected to, for example, an external device (not illustrated) mounted on the base substrate 10, and thus a circuit is formed.

The external device is not particularly limited, but includes, for example, a semiconductor chip, a ceramic capacitor, a resistor, and the like.

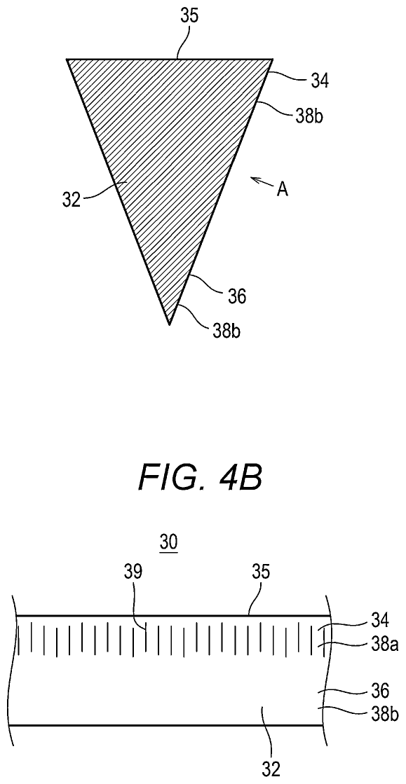

As described above, the wiring pattern 30 is formed by filling the groove 20 of the base substrate 10 with the wiring constituent material 32. More specifically, the wiring pattern 30 is a coating film formed of the wiring constituent material 32. As illustrated in FIGS. 1 and 4A, in a cross-section perpendicular to an extending direction of the wiring pattern 30 (for example, a cross-section taken along line A-A illustrated in FIG. 2), the wiring pattern 30 is also formed in a narrow V-shape in the depth direction similarly to the groove 20.

Note that in FIGS. 4A and 4B, only the wiring pattern 30 is selectively illustrated, and illustrations of the base substrate 10 and an insulating cover 50 described later are omitted.

The wiring constituent material 32 has flexibility that can follow bending deformation of the base substrate 10.

Since the wiring constituent material 32 has such high flexibility, the wiring pattern 30 formed by the wiring constituent material 32 can also satisfactorily follow the bending deformation of the base substrate 10. Therefore, better stretchability and bending resistance of the flexible transparent wiring board 100 can be achieved.

In a case of the present embodiment, as an example, the wiring constituent material 32 is a conductive paste, and is a coating film formed by curing by heat treatment (for example, a drying step described below). However, in the present disclosure, the wiring constituent material 32 may be, for example, conductive nano ink.

More specifically, the wiring constituent material 32 (conductive paste) is configured to include, for example, conductive particle and a binder resin. Note that the wiring constituent material 32 may further contain, for example, a surfactant. In addition, when the wiring constituent material 32 is the conductive nano ink, the wiring constituent material 32 (conductive nano ink) is configured to include the conductive particle, a solvent, and a dispersing agent.

The conductive particle is, for example, silver, gold, or copper metal particle 32a.

Examples of the binder resin include epoxy resin, urethane, silicone, acrylic, polyimide, thermosetting resin, and thermoplastic resin. Note that as the binder resin, one having a low Young's modulus is desirably selected so that an elastic modulus of the wiring pattern 30 in a coated state is equal to or smaller than the elastic modulus of the base substrate 10. One type of the binder resin may be used, or multiple types of binder resins may be mixed and used.

A molecular chain constituting the binder resin may be linear or branched.

A number average molecular weight of the binder resin is preferably 3,000 or more and 100,000 or less, and more preferably 8,000 or more and 50,000 or less.

Molecular weight distribution of the binder resin is not particularly limited, but is preferably less than 2.00, more preferably 1.60 or less, and still more preferably 1.40 or less.

Further, viscosity of the wiring constituent material 32 before heat treatment is preferably 100 dPa·s or more and 500 dPa·s or less, and more preferably 200 dPa·s or more and 300 dPa·s or less. Note that the viscosity here is a value measured using a rotational viscometer under a condition of 25° C.

By using such a wiring constituent material 32, while ensuring a structural strength of the wiring pattern 30 to be formed, it is possible to sufficiently achieve the flexibility and stretchability of the wiring pattern 30, as well as adhesion to the base substrate 10.

Although a method for forming the wiring pattern 30 is not particularly limited, the wiring pattern 30 can be formed, for example, by a printing method. That is, the wiring pattern 30 of the present embodiment is a printed pattern formed by printing and applying the wiring constituent material 32 having stretchability. The printing method is not particularly limited, and examples thereof include screen printing, inkjet printing, gravure printing, and offset printing. Among them, in the case of the present embodiment, the screen printing is preferably used from the viewpoint of fine resolution and stability of the wiring pattern 30. However, in the present disclosure, for example, when the conductive nano ink is used as the wiring constituent material 32, the groove 20 may be filled with the conductive nano ink by dispensing.

Further, in the case of the present embodiment, as illustrated in FIG. 1, the flexible transparent wiring board 100 includes the insulating cover 50 that covers the upper surface 10a of the base substrate 10 and the wiring pattern 30. Note that in FIG. 2, illustration of the insulating cover 50 is omitted.

According to such a configuration, the wiring pattern 30 can be well protected by the insulating cover 50.

For example, the insulating cover 50 covers the entire formation region of the wiring pattern 30 in a plan view.

The insulating cover 50 is formed with an opening (not illustrated) in which, for example, a connection terminal or a land portion of the external device is disposed. More specifically, for example, a portion constituting the connection terminal connected to the external device in the wiring pattern 30 is exposed from the insulating cover 50 through the opening of the insulating cover 50.

The insulating cover 50 may be made of the same kind of material as the base substrate 10, or may be made of a material different from the base substrate 10. Further, the insulating cover 50 may be, for example, a single layer made of the same type of resin as the base substrate 10, or may be a layer containing a resin other than the same type of resin as the base substrate 10.

The flexible transparent wiring board 100 includes, for example, a first adhesive layer (not illustrated) formed on a surface (in the case of the present embodiment, a lower surface of the insulating cover 50) of the insulating cover 50 on the base substrate 10 side. The insulating cover 50 is attached to the upper surface 10a of the base substrate 10 with the first adhesive layer.

Further, in the present disclosure, the flexible transparent wiring board 100 may further include, for example, a second adhesive layer (not illustrated) formed on a surface (in the case of the present embodiment, an upper surface of the insulating cover 50) opposite to the surface of the insulating cover 50 on the base substrate 10 side. In this case, the flexible transparent wiring board 100 is attached to the object to be attached via the second adhesive layer.

The first adhesive layer and the second adhesive layer are formed, for example, by coating an adhesive material. The adhesive material is not particularly limited, and for example, an acrylic resin can be used.

A thickness dimension of the base substrate 10 is not particularly limited, but is preferably, for example, 25 μm or more and 150 μm or less, and more preferably 50 μm or more and 125 μm or less.

The thickness dimension of the insulating cover 50 is not particularly limited, but is preferably, for example, 5 μm or more and 50 μm or less, and more preferably 10 μm or more and 20 μm or less.

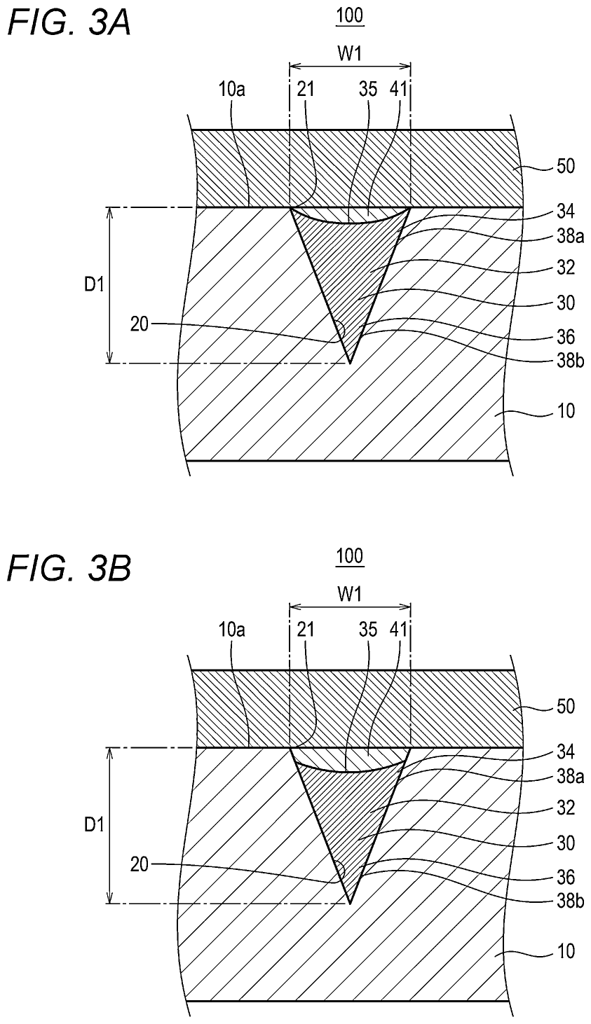

Here, in the case of the present embodiment, as illustrated in FIG. 3A, it is preferable that an upper surface 35 of the wiring constituent material 32 is a recessed surface recessed toward a widthwise central portion of the wiring constituent material 32. Thus, a layer other than the wiring constituent material 32, such as a carbon layer 41 described below, can be formed in the groove 20. The widthwise central portion of the wiring constituent material 32 can also be referred to as the widthwise central portion of the groove 20. Note that in the following description, the widthwise central portion of the wiring constituent material 32 may be simply referred to as the widthwise central portion.

However, in the present disclosure, for example, as illustrated in FIGS. 1 and 4A, the upper surface 35 of the wiring constituent material 32 may be flat and disposed flush with the upper surface 10a of the base substrate 10.

Further, in the case of the present embodiment, as illustrated in FIG. 3B, a height position of the upper surface 35 of the wiring constituent material 32 may be, for example, lower than that of an opening 21 of the groove 20, and the carbon layer 41 formed on the wiring constituent material 32 may be disposed within the groove 20.

Thus, the opening 21 of the groove 20 is closed by the carbon layer 41, so that occurrence of ion migration can be suppressed in the wiring constituent material 32 in the groove 20.

Further, since the height position of the upper surface 35 of the wiring constituent material 32 is lower than that of the opening 21 of the groove 20, it is possible to form the carbon layer 41 having a sufficient thickness on the wiring constituent material 32 while suppressing protrusion of the carbon layer 41 from the groove 20.

Further, for example, it is possible to suppress formation of horns on a portion (typically, an outer peripheral edge) of the upper surface of the wiring constituent material 32. Note that the term “horn” here means an upwardly protruding burr (protrusion) that is formed when filling the groove 20 with the wiring constituent material 32.

Note that when the carbon layer 41 is formed on the wiring constituent material 32, the wiring pattern 30 is formed by the wiring constituent material 32 and the carbon layer 41.

The carbon layer 41 is configured to include, for example, carbon particles and the binder resin. The carbon layer 41 is a coating film formed by curing by heat treatment (for example, drying treatment).

Note that in the present disclosure, when the carbon layer 41 is formed on the wiring constituent material 32, at least, it is preferable that the upper surface 35 of the wiring constituent material 32 is the recessed surface recessed toward the widthwise central portion, or the height position of the upper surface 35 is lower than that of the opening 21 of the groove 20. It is more preferable that the upper surface 35 of the wiring constituent material 32 is the recessed surface recessed toward the widthwise central portion, and the height position of the upper surface 35 is lower than that of the opening 21 of the groove 20.

In the present embodiment, the wiring pattern 30 is opaque. As illustrated in FIG. 2, in a plan view, an area of a transparent region where the wiring pattern 30 is not formed is larger than that of an opaque region where the wiring pattern 30 is formed.

According to such a configuration, although the structural strength of the wiring pattern 30 is ensured, transparency of the entire flexible transparent wiring board 100 can be well ensured.

As illustrated in FIGS. 1 and 3A, in a cross-section perpendicular to an extending direction of the groove 20, the groove 20 is formed in a narrow V-shape in the depth direction (in the case of the present embodiment, downward in FIG. 1). More specifically, a width (width W1 illustrated in FIG. 3A) of the groove 20 gradually decreases in the depth direction (downward). Note that although FIGS. 1 and 3A illustrate an example in which a lower end of the groove 20 has a sharp shape, in the present disclosure, the lower end of the groove 20 may have, for example, a rounded shape.

Here, a depth (depth D1 illustrated in FIG. 3A) of the groove 20 is, for example, less than a thickness (T1 illustrated in FIG. 1) of the base substrate 10. Thus, the wiring constituent material 32 can be satisfactorily filled into the groove 20 and the wiring pattern 30 can be formed.

Further, the width W1 of the groove 20 is, for example, 50 μm or less. Thus, it is possible to suppress the transparency, stretchability, and bending resistance of the base substrate 10 from being impaired by the wiring pattern 30.

In the case of the present embodiment, the depth D1 of the groove 20 is 80% or more of the width W1 of the groove 20. Thus, although the wiring pattern 30 is formed to have a narrow width, a cross-sectional area of the wiring pattern 30 can be sufficiently ensured, so that electrical resistance of the wiring pattern 30 can be made small.

Furthermore, the depth D1 of the groove 20 is, for example, preferably larger than the width W1 of the groove 20. In this way, although the wiring pattern 30 is formed to have a narrow width, the cross-sectional area of the wiring pattern 30 can be better ensured, so that the electrical resistance of the wiring pattern 30 can be made smaller.

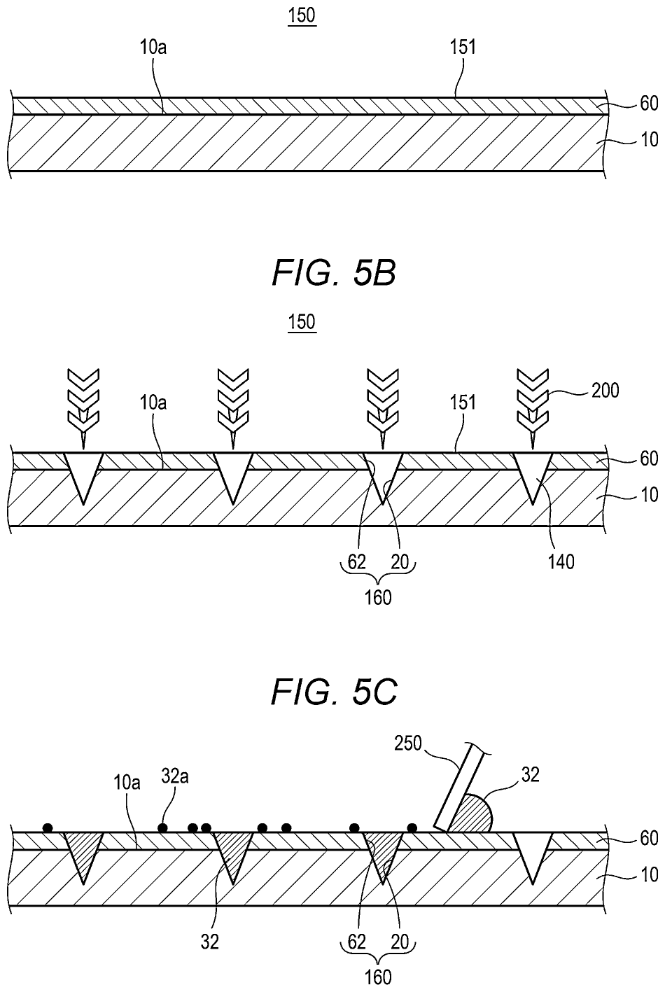

The method (hereinafter sometimes referred to as the present method) for manufacturing the flexible transparent wiring board 100 according to the present embodiment will be described below with reference to FIGS. 5A to 9C. In the present method, a step of preparing a laminate 150 including the base substrate 10 and a protective layer 60, a step of patterning the groove 20 on the base substrate 10, a step of forming the wiring pattern 30, and a step of peeling off the protective layer 60 from the base substrate 10 are performed in this order.

First, in the step of preparing the laminate 150, as illustrated in FIG. 5A, the protective layer 60 is disposed on the upper surface 10a of the base substrate 10. Then, the protective layer 60 and the base substrate 10 are fused together by applying heat and pressure using a film laminator or the like.

As the film laminator, for example, a vacuum laminator (not illustrated) is preferably used. In this way, it is possible to suppress air from being interposed between the base substrate 10 and the protective layer 60, and to bring the base substrate 10 and the protective layer 60 into sufficiently close contact with each other.

The protective layer 60 may be made of the same type of material as the base substrate 10, or may be made of a different material from the base substrate 10. Note that when the protective layer 60 is made of the material different from the base substrate 10, the protective layer 60 is preferably made of a resin material having high absorbance at a wavelength of a laser beam 200 described later.

Further, the protective layer 60 has, for example, an adhesion layer (not illustrated) having easy peelability, and is releasably attached to the base substrate 10 via the adhesion layer.

Here, the “easy peelability” of the adhesion layer is not limited as long as it is a property that allows the protective layer 60 to be peeled off from the base substrate 10 by physical treatment (for example, application of physical force) after the wiring constituent material 32 is printed or dried.

An adhesive having such easy peelability is not particularly limited, and for example, an acrylic adhesive, a rubber-based adhesive, a urethane-based adhesive, and the like can be used.

Next, in the step of patterning the groove 20, as illustrated in FIG. 5B, the base substrate 10 is irradiated with the laser beam 200 through the protective layer 60 of the laminate 150, to pattern the groove 20 on the base substrate 10.

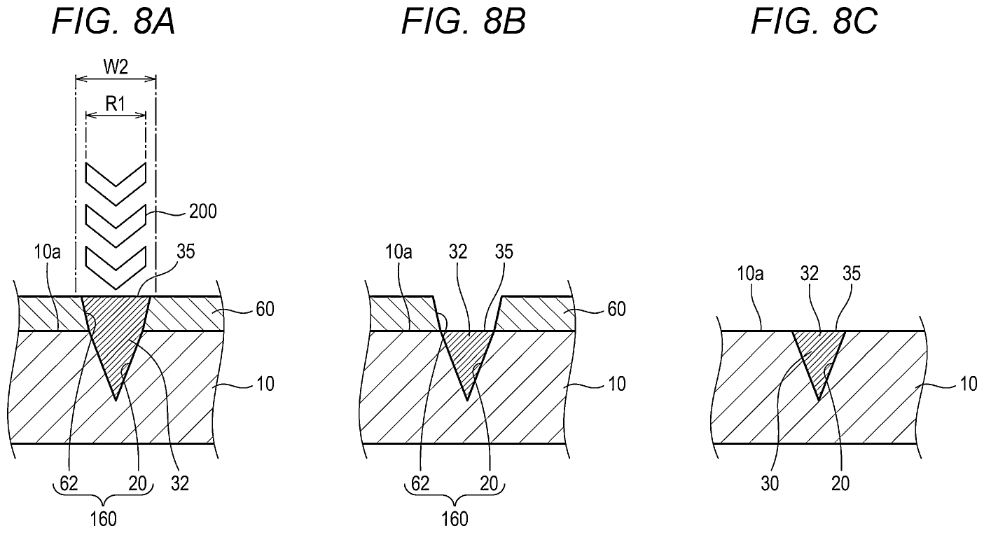

In the case of the present embodiment, through the step of patterning the groove 20, a through-hole 62 is formed in the protective layer 60, and the groove 20 communicating with the through-hole 62 is formed in the base substrate 10. More specifically, by irradiating the laser beam 200, a laser processed groove 160 having a narrow V-shape in the depth direction is formed in the laminate 150. Then, in the laser processed groove 160, a portion on an irradiation surface 151 side (in the case of the present embodiment, an upper portion) constitutes the through-hole 62 of the protective layer 60, and a portion opposite to the irradiation surface 151 side (in the case of the present embodiment, a lower portion) constitutes the groove 20 of the base substrate 10, with reference to a boundary surface between the base substrate 10 and the protective layer 60. Therefore, the width W1 of the groove 20 (see FIGS. 3A and 3B) is smaller than a width W2 of the through-hole 62 (see FIG. 8A).

Therefore, compared to a case where the groove 20 is formed by directly irradiating the laser beam 200 onto the base substrate 10 (without through the protective layer 60), a narrower groove 20 and eventually a narrower wiring pattern 30 can be formed. Furthermore, for example, it is possible to easily form the groove 20 having the width W1 smaller than a beam diameter (a diameter R1 of the laser beam 200) of a laser processing apparatus used.

Further, in the present method, the width W1 of the groove 20 to be formed can also be adjusted by adjusting the thickness dimension of the protective layer 60, that is, by adjusting a ratio of depth of the through-hole 62 to the depth of the groove 20 in the laser processed groove 160.

Further, in the present method, it is preferable that processing conditions of the laser beam 200 are set so that the depth D1 of the groove 20 to be formed is smaller than the thickness dimension of the base substrate 10 and is substantially constant regardless of a position in the extending direction of the groove 20.

Adjustment of depth of the laser processed groove 160 (eventually the depth D1 of the groove 20) is preferably performed by scanning multiple times using a step-and-repeat function of a laser apparatus (not illustrated) used. In this way, fine adjustment of the depth of the laser processed groove 160 (depth D1 of the groove 20) is facilitated. Furthermore, when irradiating the laser beam 200, damage due to heat to the base substrate 10 and the protective layer 60 can be further suppressed.

The width W1 of the groove 20 to be formed is, for example, 50 μm or less as described above.

More specifically, in the case of the present embodiment, as an example, the diameter R1 of the laser beam 200 is 18 μm. Then, the width W1 of the groove 20 is, for example, about 13 μm.

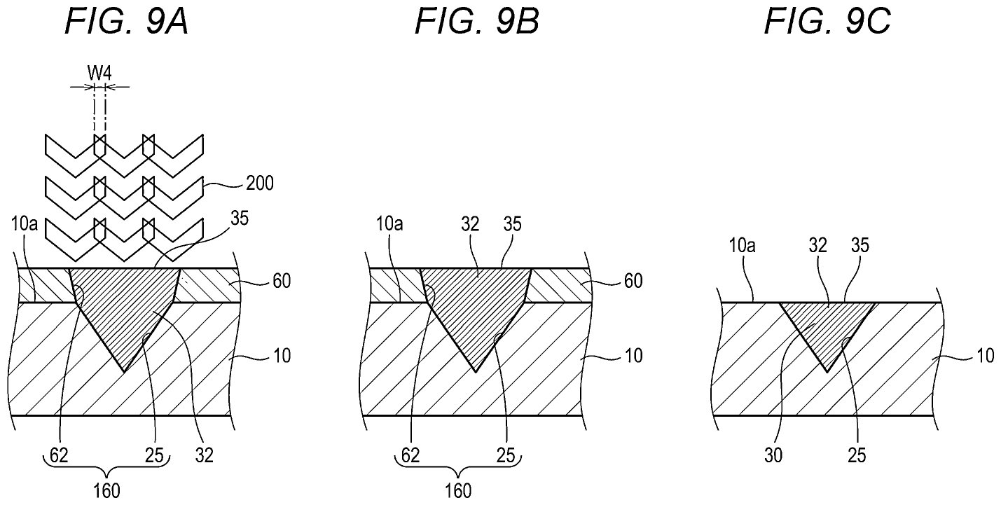

However, in the present disclosure, in addition to the groove 20 having a width W1 of 50 μm or less, as illustrated in FIG. 9A, a groove 25 having a width (for example, 50 μm or more) larger than the diameter R1 of the laser beam 200 may be further formed on the base substrate 10. In this case, the wiring pattern 30 formed in the groove 25 is used, for example, as the connection terminal connected to a land portion or a board of an electronic device or an electronic component. Note that, for example, the wiring pattern 30 (connection terminal) formed in the groove 25 may be locally plated.

As illustrated in FIG. 9A, the groove 25 is formed, for example, by irradiating the base substrate 10 with laser beams 200 by overlapping each other in a surface direction of the base substrate 10. In this case, an irradiation unit (not illustrated) of the laser processing apparatus may be moved relatively in the surface direction of the base substrate 10 while maintaining a state in which the laser beam 200 is irradiated, or an operation of once stopping the irradiation of the laser beam 200, moving the irradiation unit relatively in the surface direction of the base substrate 10, and irradiating the laser beam 200 again may be repeated multiple times. According to such a method, for example, by adjusting a moving distance of the irradiation unit of the laser processing apparatus or an overlap width (W4 illustrated in FIG. 9A) between the laser beams 200, the width of the groove 25 can be adjusted according to dimensions of the land portion, the board, or the like of the electronic device or the electronic component to be connected.

Further, by setting the overlap width W4 to be equal to or less than the diameter R1 of the laser beam 200, the laser processed groove 160 (eventually the groove 25) formed in the laminate 150 can have a narrow V-shape in the depth direction.

Note that when the overlap width W4 is set to be equal to or less than the diameter R1 of the laser beam 200, a processing speed of the laser beam 200 in a groove depth direction is faster than when forming the groove 20. Therefore, when forming the groove 25, it is preferable that the processing conditions of the laser beam 200 are set separately from the processing conditions of the laser beam 200 when forming the groove 20.

Here, in the case of the present method, an ultrashort pulse laser is, for example, used as the laser beam 200.

Thus, the narrow groove 20 can be easily formed while suppressing the damage due to heat to the base substrate 10 without using an exposure mask or the like. Therefore, while satisfactorily maintaining transparency of the base substrate 10, variations in the width W1 of the groove 20 can be suppressed. Furthermore, due to multiphoton absorption effects of the ultrashort pulse laser, it is possible to sequentially laser process the transparent base substrate 10 from the irradiation surface 151 to a bottom surface of the groove 20, so that variations in the depth D1 of the groove 20 (variations in the extending direction) can also be suppressed by adjusting laser output. Therefore, variations in the electrical resistance of the wiring pattern 30 formed by the wiring constituent material 32 filled in the groove 20 can also be suppressed.

Next, in the step of forming the wiring pattern 30, the wiring pattern 30 is formed by filling the groove 20 with the wiring constituent material 32 and drying.

More specifically, as illustrated in FIG. 5C, the wiring constituent material 32 is supplied onto the protective layer 60, and while a tip of a squeegee 250 is in contact with an upper surface of the protective layer 60, by moving the squeegee 250 (by performing squeegeeing) along the upper surface of the protective layer 60, an inside of the laser processed groove 160 (the through-hole 62 and the groove 20) is filled with the wiring constituent material 32.

Thus, the narrow wiring pattern 30 can be easily and satisfactorily formed without using a screen printing plate (not illustrated). Note that in this case, the screen printing plate may be repeatedly used as an area for temporarily holding or retracting the wiring constituent material 32. More specifically, the screen printing plate has an opening that is larger than a region encompassing the entire groove 20 in the base substrate 10 and smaller than an external dimension of the base substrate 10 in a plan view. Thus, the wiring constituent material 32 can be temporarily held or retracted on an outer peripheral edge of the opening of the screen printing plate.

Further, after squeegeeing the wiring constituent material 32, metal particles 32a of the wiring constituent material 32 and residues of the binder resin are generated on the protective layer 60, but in the step of peeling off the protective layer 60 as described later, these metal particles 32a and the residues of the binder resin are peeled off together with the protective layer 60. Therefore, it is possible to suppress the metal particles 32a of the wiring constituent material 32 and the binder resin from remaining on the wiring pattern 30 or the base substrate 10.

Furthermore, when filling the inside of the laser processed groove 160 with the wiring constituent material 32 containing the metal particles 32a, the base substrate 10 can be protected by the protective layer 60, so that the wiring pattern 30 can be formed while satisfactorily maintaining the transparency and appearance of the base substrate 10.

Here, the step of forming the wiring pattern 30 includes a drying step (heat treatment step) performed on the wiring constituent material 32 after filling the wiring constituent material 32. The wiring pattern 30 (wiring constituent material 32) is in a paste state after printing and before the drying step, and becomes in a dry state by being heated in the drying step.

In the case of the present embodiment, as an example, oven drying or a conveyor furnace is used in the drying step.

More specifically, as illustrated in FIGS. 8A to 8C, a thickness of the entire wiring constituent material 32 filled in the laser processed groove 160 (the through-hole 62 and the groove 20) shrinks by drying, and the entire wiring constituent material 32 is substantially accommodated within the groove 20. More specifically, the height position of the upper surface 35 of the wiring constituent material 32 is lowered from a state illustrated in FIG. 8A to a state illustrated in FIGS. 8B and 8C. In a completely dry state, the upper surface 35 of the wiring constituent material 32 may be flush with the upper surface 10a of the base substrate 10, or may be located below the upper surface 10a.

Here, as described above, the upper surface 35 of the wiring constituent material 32 is preferably the recessed surface recessed toward the widthwise central portion.

In the case of the present embodiment, as an example, by setting conditions of the squeegeeing in accordance with characteristics after drying of the wiring constituent material 32 used, a shape of the upper surface 35 of the wiring constituent material 32 after complete drying can be the recessed surface as described above.

Note that, as illustrated in FIGS. 9A to 9C, in the case of the groove 25 having a width wider than the diameter R1 of the laser beam 200, the wiring constituent material 32 is filled in the same procedure as the groove 20, and the wiring pattern 30 is formed.

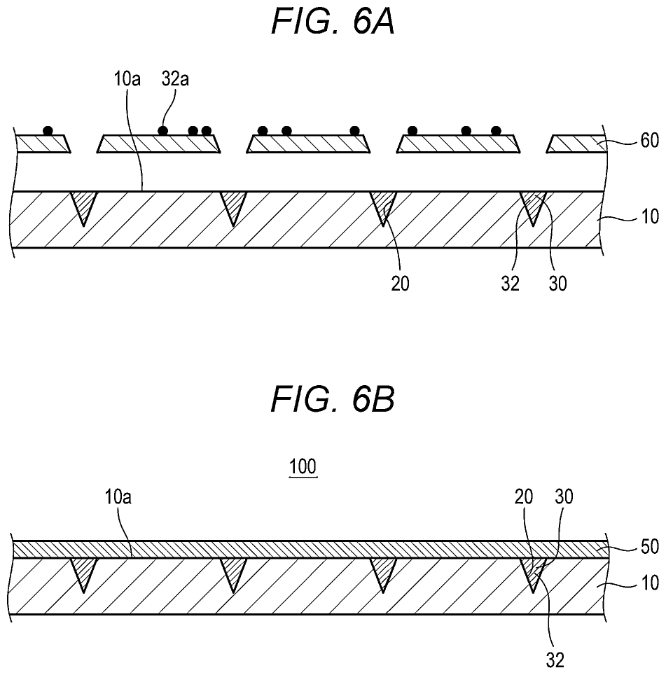

Next, in the step of peeling off the protective layer 60, as illustrated in FIG. 6A, the protective layer 60 is peeled off from the base substrate 10.

Note that in the present disclosure, the step of peeling off the protective layer 60 may be performed after the step of forming the wiring pattern 30, or may be performed during the step of forming the wiring pattern 30.

More specifically, when the step of peeling off the protective layer 60 is performed during the step of forming the wiring pattern 30, for example, the above-mentioned drying step includes a preliminary drying step and a complete drying step, and the steps are performed in an order of the preliminary drying step, the step of peeling off the protective layer 60, and the complete drying step.

In the preliminary drying step, a heating state is set to a low heating temperature and heating time that suppresses fluidity of the wiring constituent material 32, and the wiring constituent material 32 is semi-dried (semi-cured). Then, after peeling off the protective layer 60, the wiring constituent material 32 is completely dried (completely cured) in the complete drying step.

Thus, even when the heating temperature of the wiring constituent material 32 (the temperature at which the wiring constituent material 32 is completely dried and cured) is high, in the step of forming the wiring pattern 30, it is possible to suppress the above-mentioned adhesion layer (not illustrated) of the protective layer 60 from being excessively cured when the wiring constituent material 32 is heated. Therefore, in the step of peeling off the protective layer 60, the protective layer 60 can be easily peeled off from the base substrate 10.

Further, when forming the above-mentioned carbon layer 41 on the wiring constituent material 32, a step of forming the carbon layer 41 may be performed after the preliminary drying step or after the complete drying step.

In the step of forming the carbon layer 41, the carbon layer 41 is filled on the upper surface 35 of the wiring constituent material 32 in a semi-dry state or a completely dry state. The carbon layer 41 is in a pasty state after filling and before heat treatment, and becomes in the dry state by being heated by heat treatment.

The heat treatment of the carbon layer 41 may be performed simultaneously with the wiring pattern 30 in the complete drying step of the wiring pattern 30, or the drying step (heat treatment step) of the carbon layer 41 may be performed separately after the complete drying step.

Furthermore, a method for forming the carbon layer 41 is not particularly limited, and the carbon layer 41 can be formed by, for example, the printing method. The printing method is not particularly limited, and includes, for example, a screen printing method, an inkjet printing method, a gravure printing method, an offset printing method, and the like.

In the case of the present embodiment, as an example, heating in the preliminary drying step is preferably performed at a temperature of 70° C. or higher and 250° C. or lower, and more preferably 80° C. or higher and 200° C. or lower, for about 5 to 10 minutes.

Further, as an example, heating in the complete drying step is preferably performed at a temperature of 70° C. or higher and 250° C. or lower, and more preferably 80° C. or higher and 200° C. or lower, for about 30 to 90 minutes.

However, in the present disclosure, the heating conditions in the drying step can be appropriately set depending on the wiring constituent material 32, the material of the base substrate 10, or the like.

Here, in the case of the present embodiment, as illustrated in FIGS. 8A and 8B, it is preferable that the inclination angle of a sidewall of the through-hole 62 of the protective layer 60 is greater than that of a sidewall of the groove 20 of the base substrate 10.

According to such a configuration, when the wiring constituent material 32 filled in the laser processed groove 160 (the through-hole 62 and the groove 20) shrinks in the drying step, a part of the wiring constituent material 32 can smoothly slide down into the groove 20 along the through-hole 62. Therefore, in the dry state, the entire wiring constituent material 32 can be satisfactorily accommodated within the groove 20.

However, the present disclosure is not limited to this example, and the inclination angle of the sidewall of the groove 20 of the base substrate 10 may be greater than that of the sidewall of the through-hole 62 of the protective layer 60, and the inclination angle of the sidewall of the through-hole 62 of the protective layer 60 and the inclination angle of the sidewall of the groove 20 of the base substrate 10 may be the same.

Next, in the present method, for example, as illustrated in FIG. 6B, a step of attaching the insulating cover 50 onto the upper surface 10a of the base substrate 10 is performed. As an example, similarly to the protective layer 60, the insulating cover 50 and the base substrate 10 are fused together by applying heat and pressure using the film laminator or the like.

Thus, the base substrate 10 and the wiring pattern 30 can be well protected by the insulating cover 50.

However, in the present disclosure, the present method does not necessarily include the step of attaching the insulating cover 50 on the upper surface 10a of the base substrate 10. That is, the flexible transparent wiring board 100 does not need to include the insulating cover 50.

In the case of the present embodiment, as illustrated in FIG. 4B, for example, there are scratches 39 on a side surface 38a of an upper portion 34 of the wiring constituent material 32, and there are no scratches 39 on a side surface 38b of a lower portion 36 of the wiring constituent material 32. Note that in FIG. 4B, a shape of the scratch 39 is schematically illustrated.

Thus, at least a portion of the side surface 38a of the upper portion 34 of the wiring constituent material 32 can be anchored to the insulating cover 50. Therefore, peel resistance of the insulating cover 50 to the base substrate 10 can be improved.

In this way, the present method includes: the step of preparing a laminate including the base substrate 10 that is transparent and has flexibility and insulating properties, and the protective layer 60 that is releasably attached to the upper surface 10a of the base substrate 10; the step of patterning the groove 20 on the base substrate 10 by irradiating the base substrate 10 with the laser beam 200 through the protective layer 60 of the laminate; the step of forming the wiring pattern 30 by filling the groove 20 with the wiring constituent material 32 and drying; and the step of peeling off the protective layer 60 from the base substrate 10.

Then, in the step of patterning the groove 20, the groove 20 is formed in a narrow V-shape in the depth direction.

According to such a method, the narrow wiring pattern 30 can be easily formed. Thus, the formation region of the wiring pattern 30 on the base substrate 10 can be kept to a minimum, so that it is possible to suppress the transparency, stretchability, and bending resistance of the base substrate 10 from being impaired. That is, according to the present embodiment, it is possible to achieve good transparency, stretchability, and bending resistance of the flexible transparent wiring board 100.

Further, compared to method for manufacturing the flexible transparent wiring board using general screen printing method or inkjet printing method, the present method does not require jigs such as the screen printing plate and the exposure mask, and the flexible transparent wiring board 100 can be manufactured using only the film laminator, the laser processing apparatus, a screen printer, and drying equipment. That is, since the number of apparatuses and jigs required for manufacturing the flexible transparent wiring board 100 can be reduced, the flexible transparent wiring board 100 can be manufactured with higher productivity.

Furthermore, compared to the method for manufacturing the flexible transparent wiring board using general subtractive, additive, and semi-additive methods, the present method can form the wiring pattern 30 without using chemicals or water, and thus generation of waste liquid accompanying formation of the wiring pattern 30 can be suppressed. Furthermore, since there is no need to control temperature of the waste liquid, energy consumed in manufacturing the flexible transparent wiring board 100 can be satisfactorily reduced, and eventually loads on the environment can also be reduced.

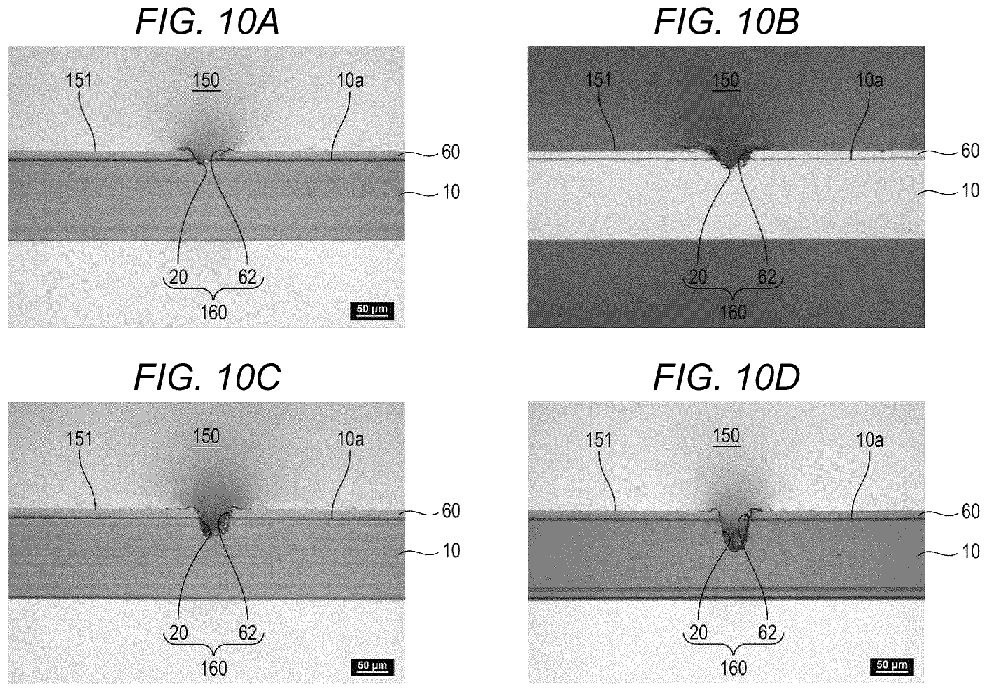

Here, FIGS. 10A to 12 illustrates enlarged photographs of the flexible transparent wiring board 100 actually obtained by the method for manufacturing the flexible transparent wiring board 100 described above. Note that FIGS. 10A to 12 illustrate images taken of the cross-section perpendicular to the extending direction of the groove 20.

As described above, in the present method, the groove 20 is patterned on the base substrate 10 by irradiating the base substrate 10 with the laser beam 200 through the protective layer 60 of the laminate 150. Therefore, as illustrated in FIG. 10A, among the base substrate 10 and the protective layer 60, the through-hole 62 is first formed in the protective layer 60. Subsequently, as illustrated in FIGS. 10B and 10C, the groove 20 is gradually formed in the base substrate 10 by the laser beam 200. Then, as illustrated in FIG. 10D, the laser processed groove 160 having a narrow V-shape formed in the depth direction is formed in the laminate 150, and eventually the groove 20 formed in a narrow V-shape in the depth direction is formed in the base substrate 10.

Thus, as described above, compared to the case where the groove 20 is formed by directly irradiating the base substrate 10 with the laser beam 200 (without through the protective layer 60), the narrower groove 20 and eventually the narrower wiring pattern 30 can be formed.

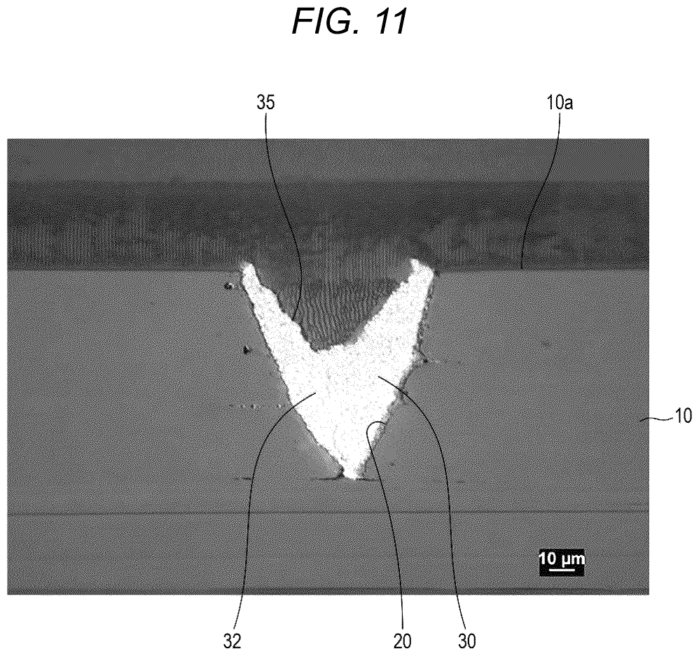

Further, FIG. 11 illustrates a state in which the groove 20 obtained in this way is filled with the wiring constituent material 32 and dried to form the wiring pattern 30, and the protective layer 60 is peeled off from the base substrate 10.

As illustrated in FIG. 11, the upper surface 35 of the wiring constituent material 32 is the recessed surface recessed toward the widthwise central portion.

This makes it easy to form a layer other than the wiring constituent material 32, such as the carbon layer 41 (not formed in a state illustrated in FIG. 11) in the groove 20, as described above.

However, in the present disclosure, the layer other than the wiring constituent material 32, such as the carbon layer 41 is not necessarily formed on the upper surface 35 of the wiring constituent material 32, which is the recessed surface recessed toward the widthwise central portion as illustrated in FIG. 11. In this case, for example, a structure can be employed in which the insulating cover 50 directly covers the wiring constituent material 32.

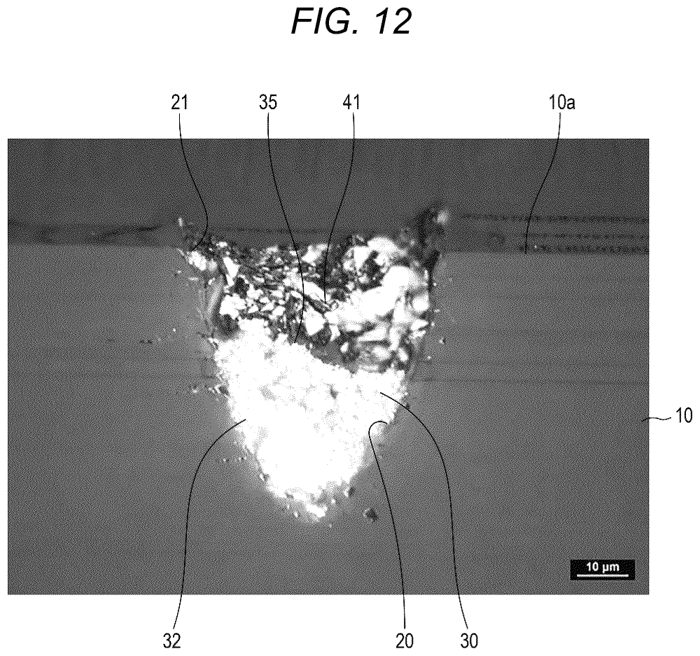

Further, FIG. 12 illustrates a state in which the carbon layer 41 is further filled on the upper surface 35 of the wiring constituent material 32 and dried, and the protective layer 60 is peeled off from the base substrate 10.

As illustrated in FIG. 12, the height position of the upper surface 35 of the wiring constituent material 32 is lower than that of the opening 21 of the groove 20.

Thus, as described above, since the opening 21 of the groove 20 is closed by the carbon layer 41, it is possible to suppress the occurrence of the ion migration in the wiring constituent material 32 in the groove 20. In addition, since the height position of the upper surface 35 of the wiring constituent material 32 is lower than that of the opening 21 of the groove 20, it is possible to form the carbon layer 41 having a sufficient thickness on the wiring constituent material 32 while suppressing the protrusion of the carbon layer 41 from the groove 20.

Although the embodiments have been described above with reference to the drawings, these embodiments are merely examples of the present disclosure, and various configurations other than those described above can also be employed.

The above embodiments include the following technical ideas.

(1) A flexible transparent wiring board including: a base substrate; and wiring, in which the base substrate is transparent and has flexibility and insulating properties, a groove is formed on an upper surface of the base substrate, the wiring is formed of a wiring constituent material filled in the groove, and the groove is formed in a narrow V-shape in a depth direction.

(2) The flexible transparent wiring board according to (1), in which an upper surface of the wiring constituent material is a recessed surface recessed toward a widthwise central portion of the wiring constituent material.

(3) The flexible transparent wiring board according to (1) or (2), in which a side surface of an upper portion of the wiring constituent material has a scratch, and a side surface of a lower portion of the wiring constituent material does not have the scratch.

(4) The flexible transparent wiring board according to (1) or (2), further including a carbon layer, in which a height position of an upper surface of the wiring constituent material is lower than that of an opening of the groove, and the carbon layer is formed on the wiring constituent material and within the groove.

(5) The flexible transparent wiring board according to (1) or (2), in which the wiring is opaque, and in a plan view, an area of a transparent region where the wiring is not formed is larger than that of a region where the wiring is formed.

(6) The flexible transparent wiring board according to (1) or (2), in which a depth of the groove is less than a thickness of the base substrate.

(7) The flexible transparent wiring board according to (1) or (2), in which a width of the groove is 50 μm or less.

(8) The flexible transparent wiring board according to (1) or (2), in which a depth of the groove is 80% or more of a width of the groove.

(9) The flexible transparent wiring board according to (8), in which the depth of the groove is greater than the width of the groove.

(10) The flexible transparent wiring board according to any one of (1) to (9), in which the wiring constituent material has flexibility that can follow bending deformation of the base substrate.

(11) The flexible transparent wiring board according to any one of (1) to (10), further including an insulating cover, in which the insulating cover is formed to cover the upper surface of the base substrate and the wiring.

(12) A method for manufacturing a flexible transparent wiring board, the method including: preparing a laminate including a base substrate that is transparent and has flexibility and insulating properties, and a protective layer that is releasably attached to an upper surface of the base substrate; forming a groove in the base substrate by irradiating the base substrate with a laser beam through the protective layer of the laminate; forming wiring by filling the groove with a wiring constituent material and drying; and peeling the protective layer from the base substrate, in which the groove is formed in a narrow V-shape in a depth direction.

(13) The method for manufacturing the flexible transparent wiring board according to (12), in which an ultrashort pulse laser is used as the laser beam.

(14) The method for manufacturing the flexible transparent wiring board according to (12) or (13), in which by forming the groove, a through-hole is formed in the protective layer, and the groove communicating with the through-hole is formed in the base substrate, and an inclination angle of a sidewall of the through-hole is greater than that of a sidewall of the groove.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A flexible transparent wiring board comprising:
a base substrate; and
wiring, wherein
the base substrate is transparent and has flexibility and insulating properties,
a groove is formed on an upper surface of the base substrate,
the wiring is formed of a wiring constituent material filled in the groove, and
the groove is formed in a narrow V-shape in a depth direction.

2. The flexible transparent wiring board according to claim 1, wherein an upper surface of the wiring constituent material is a recessed surface recessed toward a widthwise central portion of the wiring constituent material.

3. The flexible transparent wiring board according to claim 1, wherein a side surface of an upper portion of the wiring constituent material has a scratch, and a side surface of a lower portion of the wiring constituent material does not have the scratch.

4. The flexible transparent wiring board according to claim 1, further comprising a carbon layer, wherein
a height position of an upper surface of the wiring constituent material is lower than that of an opening of the groove, and
the carbon layer is formed on the wiring constituent material and within the groove.

5. The flexible transparent wiring board according to claim 1, wherein
the wiring is opaque, and
in a plan view, an area of a transparent region where the wiring is not formed is larger than that of an opaque region where the wiring is formed.

6. The flexible transparent wiring board according to claim 1, wherein a depth of the groove is less than a thickness of the base substrate.

7. The flexible transparent wiring board according to claim 1, wherein a width of the groove is 50 μm or less.

8. The flexible transparent wiring board according to claim 1, wherein a depth of the groove is 80% or more of a width of the groove.

9. The flexible transparent wiring board according to claim 8, wherein the depth of the groove is greater than the width of the groove.

10. The flexible transparent wiring board according to claim 1, wherein the wiring constituent material has flexibility that can follow bending deformation of the base substrate.

11. The flexible transparent wiring board according to claim 1, further comprising an insulating cover, wherein
the insulating cover is formed to cover the upper surface of the base substrate and the wiring.

12. A method for manufacturing a flexible transparent wiring board, the method comprising:
preparing a laminate including a base substrate that is transparent and has flexibility and insulating properties, and a protective layer that is releasably attached to an upper surface of the base substrate;
forming a groove in the base substrate by irradiating the base substrate with a laser beam through the protective layer of the laminate;
forming wiring by filling the groove with a wiring constituent material and drying; and
peeling the protective layer from the base substrate, wherein
the groove is formed in a narrow V-shape in a depth direction.

13. The method for manufacturing the flexible transparent wiring board according to claim 12, wherein an ultrashort pulse laser is used as the laser beam.

14. The method for manufacturing the flexible transparent wiring board according to claim 12, wherein
by forming the groove,
a through-hole is formed in the protective layer, and the groove communicating with the through-hole is formed in the base substrate, and
an inclination angle of a sidewall of the through-hole is greater than that of a sidewall of the groove.
